(19) United States
(12) Patent Application Publication
(10) Pub. No.: US 2025/0076847 A1
(43) Pub. Date: Mar. 6, 2025

(54) METHOD AND COMPUTING DEVICE FOR MANUFACTURING SEMICONDUCTOR DEVICE USING TRANSFORMER MODEL

(71) Applicant: SAMSUNG ELECTRONICS CO., LTD., SUWON-SI (KR)

(72) Inventors: Soo Yong LEE, Suwon-si (KR); Jee Yong LEE, Suwon-si (KR); Seung Hune YANG, Suwon-si (KR); Seong Tae JEONG, Suwon-si (KR)

(21) Appl. No.: 18/779,613

(22) Filed: Jul. 22, 2024

(30) Foreign Application Priority Data
Sep. 1, 2023 (KR) 10-2023-0116105

(51) Int. Cl. G05B 19/4099

(52) U.S. Cl. CPC G05B 19/4099; G05B 2219/45031

(57) ABSTRACT

A method for manufacturing a semiconductor device includes extracting coordinates of vertices of patterns from an optical proximity corrected layout data for an optical proximity corrected layout including the patterns; and inputting the coordinates of the vertices into a transformer model to output whether there is a Mask Rule Check (MRC) violation on the optical proximity corrected layout data.

### CROSS-REFERENCE TO RELATED APPLICATION

This application claims priority under 35 U.S.C. 119 to Korean Patent Application No. 10-2023-0116105, filed on Sep. 1, 2023, in the Korean Intellectual Property Office, and all the benefits accruing therefrom, the contents of which in its entirety are herein incorporated by reference.

### BACKGROUND

### 1. Field of the Inventive Concepts

The present inventive concepts relate to a method for manufacturing a semiconductor device using a transformer model and computing device.

### 2. Description of the Related Art

In a semiconductor process, a photolithography process using a mask may be performed to form a pattern on a semiconductor substrate, such as a wafer. The mask may be referred to as a pattern transcription in which a pattern shape of an opaque material is formed on a transparent base layer material. To manufacture such a mask, a layout on the required pattern is first designed, and then the optical proximity corrected layout data acquired through an OPC (Optical Proximity Correction) is delivered as MTO (Mask Tape-Out) design data. Thereafter, a mask data preparation (MDP) is performed on the basis of the MTO design data, and an exposure process or the like may be performed on the mask substrate. On the other hand, a pattern may be formed on the semiconductor substrate, by performing a PR pattern formation process on the semiconductor substrate using a mask, an etching process using the PR pattern, and the like.

### SUMMARY

Aspects of the present inventive concepts provide a method for manufacturing a semiconductor device that may more accurately detect the presence or absence of a Mask Rule Check (MRC) violation.

Aspects of the present inventive concepts also provide a computing device that may more accurately detect the presence or absence of the MRC violation.

However, aspects of the present inventive concepts are not restricted to the one set forth herein. The above and other aspects of the present inventive concepts will become more apparent to one of ordinary skill in the art to which the present inventive concepts pertain by referencing the detailed description of the present inventive concepts given below.

According to embodiments of the present inventive concepts, a method for manufacturing a semiconductor device includes extracting coordinates of vertices of patterns from optical proximity corrected layout data for an optical proximity corrected layout, including the patterns; and inputting the coordinates of the vertices into a trained transformer model to determine there is a Mask Rule Check (MRC) violation on the optical proximity corrected layout data.

According to some example embodiments of the present inventive concepts, a method for manufacturing a semiconductor device includes acquiring learning data, which includes defective layout data that violates a Mask Rule Check (MRC), and normal layout data that does not violate the MRC; tokenizing the learning data; generating a transformer model, using the tokenized learning data; tokenizing optical proximity corrected layout data; and inputting the tokenized optical proximity corrected layout data to the transformer model to output whether there is an MRC violation on the optical proximity corrected layout data.

According to some example embodiments of the present inventive concepts, a computing device includes a memory which stores instructions; and at least one processor which executes the instructions, wherein the at least one processor: generates a learned transformer model, using defective layout data that violates a Mask Rule Check (MRC) and normal layout data that does not violate the MRC, extracts coordinates of vertices of patterns from optical proximity corrected layout data on an optical proximity corrected layout including the patterns, and inputs the coordinates of the vertices to the transformer model to output whether there is a MRC violation on the optical proximity corrected layout data.

### BRIEF DESCRIPTION OF THE DRAWINGS

The above and other aspects and features of the present inventive concepts will become more apparent by describing in detail exemplary embodiments thereof with reference to the attached drawings, in which:

FIG. 1 is a flowchart for a method for manufacturing a semiconductor device, according to various embodiments;

FIG. 2 is a diagram for explaining learning data, according to various embodiments;

FIG. 3 is a diagram for a method for detecting the presence or absence of an MRC violation, according to various embodiments;

FIGS. 4 and 5 are diagrams for a transformer model of FIG. 1, according to various embodiments;

FIGS. 6 and 7 are diagrams for a method of manufacturing the semiconductor device, according to various embodiments;

FIG. 8 is a diagram for a method for manufacturing the semiconductor device, according to various embodiments;

FIG. 9 is a flowchart for a method for manufacturing the semiconductor device, according to various embodiments;

FIG. 10 is a flowchart for a method for manufacturing the semiconductor device, according to various embodiments;

FIG. 11 is a diagram for explaining S160 of FIG. 10, according to various embodiments;

FIG. 12 is a flowchart showing a method for manufacturing the semiconductor device, according to various embodiments; and

FIG. 13 is a block diagram showing a computing device, according to various embodiments.

### DETAILED DESCRIPTION OF THE EMBODIMENTS

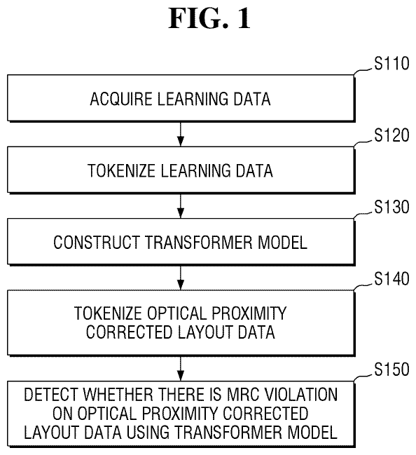

FIG. 1 is a flowchart for a method for manufacturing a semiconductor device, according to various embodiments.

Referring to FIG. 1, the learning data may be acquired (S110), the learning data may be tokenized (S120), and a transformer model may be constructed (S130). The optical proximity corrected layout data may be tokenized (S140), and an MRC violation may be detected based on the optical proximity corrected layout data using the transformer model (S150).

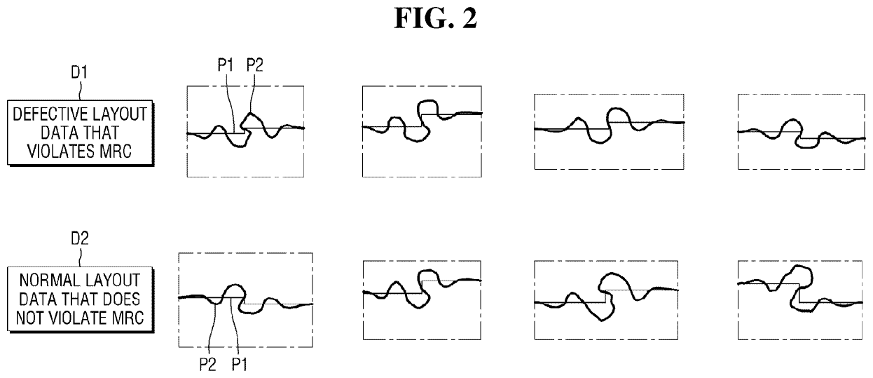

FIG. 2 is a diagram for explaining learning data, according to various embodiments.

Referring to FIG. 2, the learning data may include defective layout data D1 that violates an MRC (Mask Rule Check), and normal layout data D2 that does not violate the MRC. The defective layout data D1 that violates the MRC may include data about a defective layout that violates the MRC. The normal layout data D2 that does not violate the MRC may include data about a normal layout that does not violate the MRC. The defective layout that violates the MRC and the normal layout that does not violate the MRC may each include a mask pattern P1 and an optical proximity corrected pattern P2.

In various embodiments, the optical proximity corrected pattern P2 may be generated by performing OPC on the mask pattern P1. The Optical Proximity Correction (OPC) may be a method for correcting the layout of mask pattern P1 to suppress an optical proximity effect (OPE), which occurs due to the influence between adjacent patterns in the exposure process with miniaturization of patterns. While performing the OPC, the shape and position of the mask pattern P1 may be finely corrected (biased).

In various embodiments, the MRC may involve checking on the restrictions of a width or an interval within which a pattern can be maintained when manufacturing the mask. For example, when manufacturing the mask, there may be restrictions in which the width of the pattern may not be made smaller than a set minimum width or an interval between the patterns may not be made smaller than a set minimum interval, i.e., mask process restrictions. The MRC execution or verification may refer to the process of checking whether the above-mentioned restrictions are observed for the optical proximity corrected layout. Final optical proximity corrected layout data may be obtained by executing the MRC. The final optical proximity corrected layout data may then be delivered to the mask manufacturing team as MTO design data for mask manufacturing. For example, the MTO design data may have a data format such as a GDS (Graphic Data System) or an OASIS (Open Artwork System Interchange Standard).

The defective layout data D1 that violates the MRC (Mask Rule Check) and the normal layout data D2 that does not violate the MRC may each have a data format such as GDS (Graphic Data System).

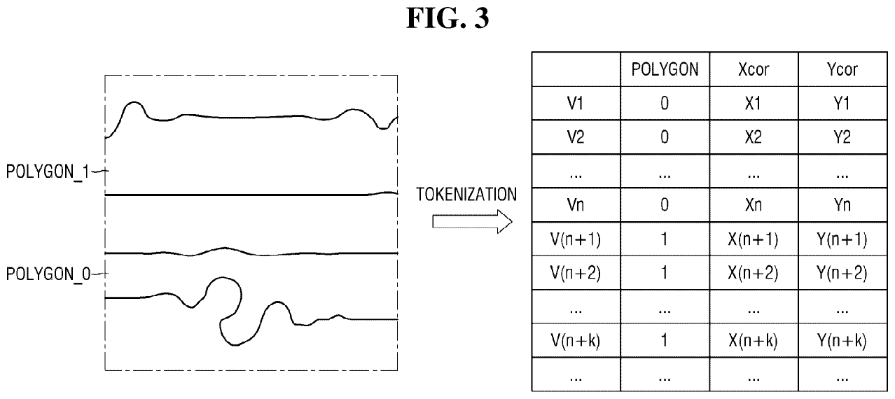

FIG. 3 is a diagram for a method for detecting the presence or absence of an MRC violation, according to various embodiments.

Referring to FIG. 3, the layout data, which may be the learning data, includes data about a layout, including a plurality of polygons POLYGON_0 and POLYGON_1. The polygons POLYGON_0 and POLYGON_1 may refer to the optical proximity corrected pattern included in the optical proximity corrected layout. The number of polygons POLYGON_0 and POLYGON_1 is not limited to that shown in FIG. 3.

In various embodiments, each of the polygons POLYGON_0 and POLYGON_1 may include a plurality of vertices. For example, the first polygon POLYGON_0 may include a plurality of first vertices V1 to Vn (where n is a natural number), and the second polygon POLYGON_1 may include a plurality of second vertices V(n+1) to V(n+k) (where k is a natural number).

In various embodiments, the tokenization may include conversion of learning data into a format for input into a transformer model.

In various embodiments, the learning data may be tokenized by extracting the coordinates (Xcor, Ycor) of polygon vertices and polygon information POLYGON, where the polygon information POLYGON represents a value indicating a polygon, where for example, a value 0 indicates the first polygon POLYGON_0 and the value 1 indicates the second polygon POLYGON_1.

For example, a value 0 indicating the first polygon POLYGON_0 and coordinates (X1, Y1) of the first vertex V1, the value 0 indicating the first polygon POLYGON_0 and coordinates (X2, Y2) of the first vertex V2 to the value 0 indicating the first polygon POLYGON_0 and coordinates (Xn, Yn) of an nth vertex Vn may be extracted. A value 1 indicating the second polygon POLYGON_1 and coordinates (X(n+1), Y(n+1)) of the second vertex V(n+1), the value 1 indicating the second polygon POLYGON_1 and coordinates (X(n+2), Y(n+2)) of the second vertex V(n+2) to the value 1 indicating the second polygon POLYGON_1 and coordinates (V(n+k), Y(n+k)) of the second vertex X(n+k) may be extracted.

In various embodiments, the transformer model may be constructed (S130) through learning using the learning data tokenized in S120. The transformer model may be learned (trained) to receive input of the tokenized learning data and output MRC violations based on the learning data.

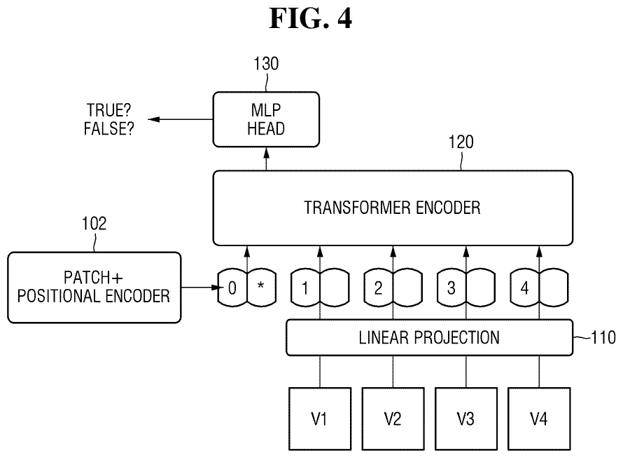

FIGS. 4 and 5 are diagrams for a transformer model of FIG. 1, according to various embodiments.

Referring to FIG. 4, the transformer model may include a linear projection block 110, a transformer encoder 120, and a multi-layer perceptron (MLP) head block 130.

Vertices V1 to V4 will be explained as an example. In various embodiments, the vertices V1 to V4 may be input into the transformer model. The vertices V1 to V4 may be the learning data tokenized in S120 of FIG. 1. The vertices V1 to V4 may be divided into patch units and flattened. The flattened patches may constitute sequence data in the form of a sequence.

In various embodiments, the linear projection block 110 may project the flattened patches into embedding vectors.

A learnable class token * may be added to the embedding vector, where the learnable class token * may be placed at the beginning of each of the embedding vectors. Position information (0 to 4) may be added (102) to each embedding vector, and embedding pairs may be generated. The position information (0 to 4) may represent a position within vertices V1 to V4 of each patch corresponding to each embedding vector.

In various embodiments, the transformer encoder 120 may perform a self-attention on the embedding pairs. The MLP HEAD block 130 may output the presence or absence of the MRC violations of the learning data on the basis of the attention results. The output of the class token * may be added to the MLP HEAD block 130 to output the presence or absence of the MRC violation of the learning data.

Referring to FIG. 5, a transformer encoder 140a may include a multi-head attention block 143, normalization blocks 142 and 144, and an MLP 145. The transformer encoder 140a of FIG. 5 may correspond to the transformer encoder 120 of FIG. 4. The embedded patch 141 may correspond to the embedded pairs described using FIG. 4.

An encoding operation may be repeated N times, where N can be the number of vertices. The multi-head attention block 143 may perform the self-attention on the basis of the embedded patches 141.

Referring again to FIG. 1, the optical proximity corrected layout data may be tokenized (S140). The optical proximity corrected layout data may include data about the optical proximity corrected layout. The tokenization of optical proximity corrected layout data may be similar to that described using FIG. 3. The optical proximity corrected layout data may be tokenized by extracting the coordinates of the vertices of the polygons of the optical proximity corrected layout.

In various embodiments, an MRC violation on the optical proximity corrected layout data may be detected using the transformer model (S150). The optical proximity corrected layout data may have a data format such as a GDS.

In various embodiments, a learned deep learning model may be constructed on the basis of a CNN (Convolution Neural Net) or the like to output whether there is an MRC violation of the optical proximity corrected layout. The optical proximity corrected layout data may be CAD data in vector graphic format, such as a GDS. To input the optical proximity corrected layout data into the deep learning model, the optical proximity corrected layout may be rasterized to generate an image. Rasterization may refer to a process of converting the optical proximity corrected layout into pixel or bitmap data.

A trade-off may occur between the accuracy of the deep learning model and a TAT (Turn Around Time), depending on the pixel size at the time of the rasterization. Even with the same optical proximity corrected layout, the output of the deep learning models may vary depending on the rasterization grid. Furthermore, if the data base unit of the semiconductor blueprint is smaller than the size of the rasterization grid, the information on the semiconductor blueprint may be damaged in the rasterization process.

In various embodiments, the presence or absence of the MRC violation is detected using geometric features of the optical proximity corrected layout, for example, a width, an interval, a distance between corners, or the like. However, if the optical proximity corrected layout is made up of curves, it is difficult to identify the geometric features, and even if the optical proximity corrected layout satisfies conditions of the geometric features, a failure may occur in the mask manufacturing.

In various embodiments, the method for manufacturing the semiconductor tokenize the optical proximity corrected layout data to extract the coordinates of vertices, and inputs the tokens into the transformer model to determine whether there is an MRC violation. Data in a graphical format may be input to the transformer model without a rasterization to output the presence or absence of MRC violations. Therefore, it is possible to more accurately determine whether there is an MRC violation on the optical proximity corrected layout data. Because the rasterization process is omitted, it is possible to determine whether there is an MRC violation regardless of the magnitude of the rasterization grid, the size of the pixels, and the like. The geometric features of the optical proximity corrected layout may not be specified.

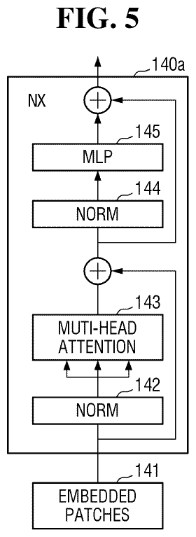

FIGS. 6 and 7 are diagrams for a method for manufacturing a semiconductor device according to embodiments. FIGS. 6 and 7 are enlarged views of the polygons in the layout of FIG. 3.

Referring to FIGS. 6 and 7, control points may be formed on the mask pattern (P1 of FIG. 2). The control points may move in various directions by the OPC execution. The moved control points may be connected to form an optical proximity corrected pattern OPC (P2 of FIG. 2). The vertices V1 to V(i+6) may be the moved control points.

In various embodiments, the polygon may be formed by connecting vertices V1 to V(i+6). The polygon may be divided into segments S that connect two vertices adjacent to each other. The learning data may be tokenized by extracting the coordinates of the vertices that make up the segment S.

Referring to FIG. 6, the polygon may be formed by connecting the vertices V1 to V(i+6). The coordinates of vertex V1, coordinates of vertex V(i+1), coordinates of vertex V(i+2), coordinates of vertex V(i+3), coordinates of vertex V(i+4), coordinates of vertex V(i+5) and the coordinates of vertex V(i+6) may be extracted from the learning data. The coordinates of all vertices of the polygon may be extracted. The learning data may be tokenized accordingly.

Referring to FIG. 7, the polygon may be formed by connecting some of the vertices V1 to V(i+6) with edges. The polygon may be formed in a Bezier curve or a B-spline curve with the vertices V1 to V(i+6), as control points. The polygon may be formed by connecting the vertices V1, V(i+3), and V(i+6). The coordinates of the vertex V1, the coordinates of the vertex V(i+3), and the coordinates of the vertex V(i+6) may be extracted from the learning data. The coordinates of control points V1, V(i+3), and V(i+6) forming the polygon among the control points V1 to V(i+6) may be extracted. The coordinates of some control points V1, V(i+3), and V(i+6) among the control points V1 to V(i+6) may be extracted. The learning data may be tokenized accordingly. A processor may extract coordinates of one or more control points of the curve as the coordinates of the vertices.

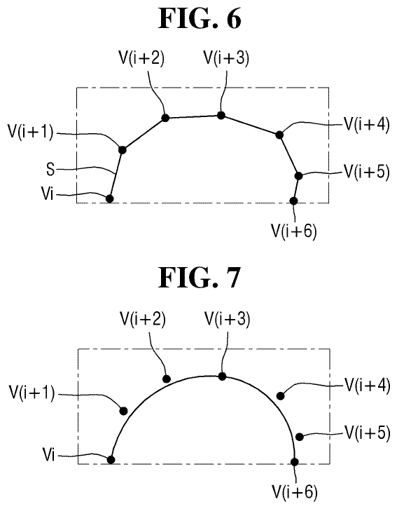

FIG. 8 is a diagram for a method for manufacturing a semiconductor device, according to various embodiments. FIG. 8 is a diagram for explaining the method for manufacturing the semiconductor device using layout data of the learning data, as an example. For convenience of explanation, the explanation will focus on the points that are different from those explained using FIGS. 1 to 5.

Referring to FIG. 8, in a method for detecting the presence or absence of the MRC violation. The learning data may be tokenized by extracting the coordinates and polygon information of each vertex of the one or more polygons. The polygon information may be extracted using a command CMD. A command L refers to a line, and a command E may indicate the last vertex in the corresponding polygon. Therefore, polygons may be distinguish using the command CMD.

For example, a vertex Vn may be indicated as being the last vertex of the first polygon POLYGON_0 using the command E, and another vertex V(n+k) may be indicated as being the last vertex of the second polygon POLYGON_1 using the command E. The first vertex V1 may be indicated as being a vertex of the first polygon POLYGON_0 other than the last vertex by using the command L.

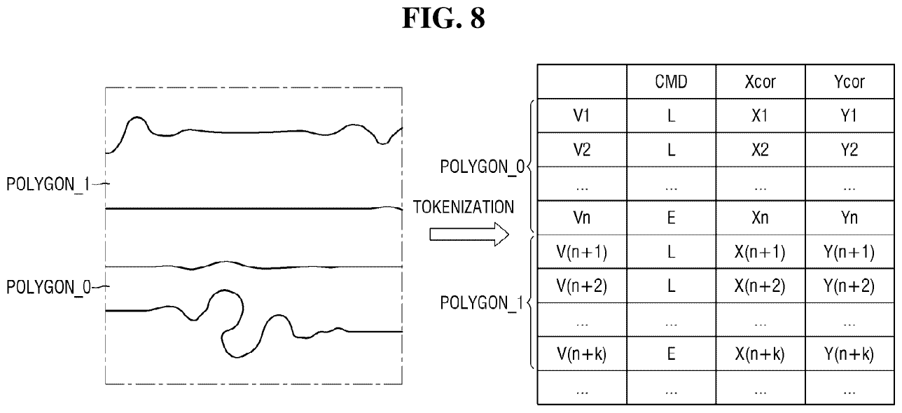

FIG. 9 is a flowchart for a method for manufacturing a semiconductor device, according to various embodiments.

Referring to FIG. 9, in the method for manufacturing the semiconductor device, a transformer model for detecting the presence or absence of an MRC violation may be learned on the basis of knowledge distillation.

In various embodiments, a teacher model 100 and a student model 200 may represent neural networks of different sizes, where the teacher model 100 may be a neural network larger in size than the student model 200. The teacher model 100 and student model 200 may both be trained to recognize the same objects. For example, the teacher model 100 may be configured with more hidden layers or more nodes and weights than the student model 200, or a combination thereof.

In various embodiments, the teacher model 100 is a model that recognizes target data with high accuracy using a sufficiently large number of features extracted from the target data.

In various embodiments, the student model 200 is a neural network that is smaller in size than the teacher model 100 and has faster recognition speed than the teacher model 100 due to its smaller size, for example, due to fewer calculations. The student model 200 may be trained on the basis of the teacher model 100. For example, the output data of the teacher model 100 may be a value of logit, a probability value, or an output value of a classification layer derived from a hidden layer of the teacher model 100. Accordingly, it is possible to obtain the student model 200, which has a faster recognition speed than the teacher model 100, while outputting the same value as the teacher model 100. Such a learning method may be called model compression.

In various embodiments, the teacher model 100 may be based on a model architecture different from the student model 200, where for example, the student model 200 may be a transformer model and the teacher model 100 may be a Convolutional Neural Network (CNN).

In various embodiments, the teacher model 100 may be, for example, a CNN (Convolutional Neural Network)-based model. The teacher model 100 may receive input of the rasterized learning data DO and output the absence or absence of the MRC violation on the learning data DO.

In various embodiments, the student model 200 may be learned from the teacher model 100 on the basis of the knowledge distillation. The knowledge distillation is a way of transferring knowledge from a large number of large models learned through an ensemble technique to a new model. The knowledge distillation is one way of reducing model size. The model compression is a technique of learning the student model 200, using the output data of the teacher model 100 instead of a correct answer data that is a ground truth label.

In various embodiments, the student model 200 may be the transformer model described using FIGS. 1 to 8. Therefore, the performance of the transformer model may be improved. The transformer model may be learned using the tokenized learning data, and may be learned from the teacher model learned using the rasterized learning data DO. That is, the transformer model may receive input of the learning data tokenized and the rasterized learning data DO.

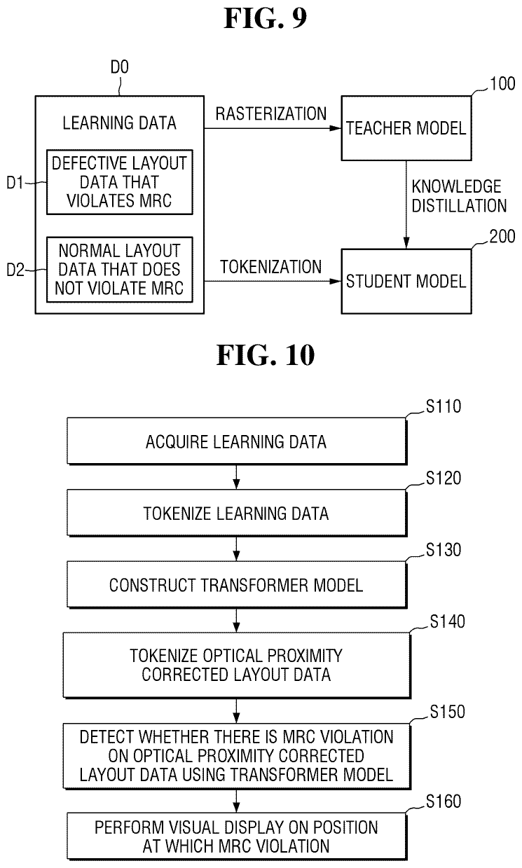

FIG. 10 is a flowchart for a method for manufacturing a semiconductor device, according to various embodiments.

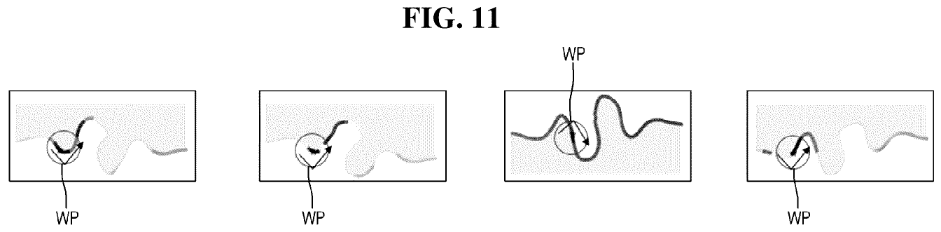

FIG. 11 is a diagram for explaining S160 of FIG. 10. For convenience of explanation, the explanation will focus on the features that are different from those explained using FIGS. 1 to 8.

Referring to FIG. 10, the method for manufacturing a semiconductor device according to some embodiments may further include performing a visual display on a position at which the MRC violation occurs (S160), where S110 to S150 are the same as shown in FIG. 1.

Referring to FIG. 11, an attention map may be generated according to the attention results of the transformer model. It possible to visually confirm the position WP at which the MRC violation occurs, accordingly. The transformer may be utilized as an explainable AI (XAI) through visualization using the attention map. The attention map may be, for example, a neural network technique for implementing the phenomenon of human visual attention.

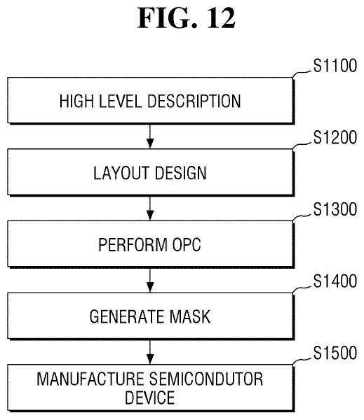

FIG. 12 is a flowchart showing a method for manufacturing a semiconductor device according to some embodiments.

In various embodiments, a high-level design of a semiconductor integrated circuit is performed (S1100).

In various embodiments, the high-level design may mean describing an integrated circuit to be designed in a high-level language of the computer language, where for example, a high-level language, such as C, may be used. Circuits designed by the high-level design may be more specifically represented by register transfer level (RTL) encoding or simulation. The code generated by the register transfer level encoding may be converted into a netlist and synthesized into the entire semiconductor device. The synthesized schema circuit may be verified by a simulation tool, and an adjustment process may be accompanied depending on the verification results.

In various embodiments, a layout design for implementing a logically completed semiconductor device on a silicon substrate may be performed (S1200). For example, a layout design may be performed with reference to a schematic circuit synthesized in a high-level design or a netlist corresponding thereto. The layout design may include routing procedures, which place and connect various standard cells provided in the cell library according to defined design rules.

In various embodiments, the cell libraries for the layout design may also include information about operation, speed, power consumption, and the like of the standard cell. The cell libraries for representing specific gate-level circuits, as layouts are defined in most layout design tools.

In various embodiments, the layout may be a procedure for defining the shape or size of a pattern for configuring transistors and metal wirings actually formed on the silicon substrate. For example, in order to actually form an inverter circuit on the silicon substrate, a PMOS, a NMOS, a N-WELL, a gate electrode, and layout patterns such as metal wirings placed on them may be appropriately placed. To this end, an appropriate inverter among the inverters already defined in the cell library may be first searched and selected.

In various embodiments, routing may be performed on the selected and placed standard cells, where routing with upper level wirings may be performed on the selected and placed standard cells. The standard cells may be connected to each other for the design through the routing procedures. The series of processes S1100 and S1200 described above may be performed automatically or manually by the layout design tool. Additionally, the placement and routing of the standard cells may be performed automatically using a separate Place & Routing tool.

In various embodiments, the layout may be validated by determining whether there is a portion that violates the design rule. The items to be verified may include a Design Rule Check (DRC), which verifies that the layout is correctly set and suitable for the design rules, an Electrical Rule Check (ERC), which verifies whether the layout is correctly set without any internal electrical interruptions, a Layout vs Schematic (LVS), which checks whether the layout matches the gate level netlist.

In various embodiments, the OPC is performed (S1300).

As a result, the optical proximity corrected layout is formed. The optical proximity corrected layout determines whether there is a MRC violation. The determination may be performed using the presence or absence of an MRC violation detection method, as described with reference to FIGS. 1 to 11. It is possible to tokenize the layout data subjected to OPC for the optical proximity corrected layout, and detect whether the layout data subjected to OPC violates the MRC, using the transformer model.

If the optical proximity corrected layout does not violate the MRC, a photomask is manufactured on the basis of the optical proximity corrected layout. A photomask may be manufactured on the basis of the optical proximity corrected layout not having an MRC violation.

In various embodiments, a photomask is manufactured on the basis of the corrected layout changed by optical proximity compensation (S1400).

In various embodiments, a photomask may be manufactured, but is not limited to the layout patterns using a chromium film coated on a glass substrate.

In various embodiments, a semiconductor device is manufactured using a photomask (S1500).

In the manufacturing process of the semiconductor device using a photomask, various types of exposure and etching processes may be repeated. Through such processes, the forms of patterns configured at the time of layout design may be sequentially formed on the silicon substrate.

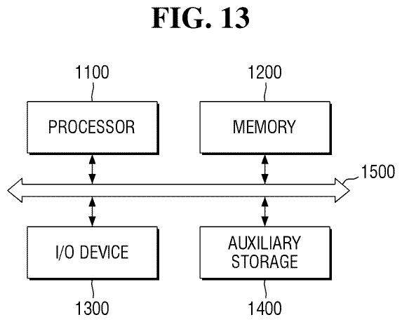

FIG. 13 is a block diagram showing a computing device according to some embodiments.

Referring to FIG. 13, the computing device includes a processor 1100, a memory 1200, an input/output device 1300, an auxiliary storage 1400, and a system interconnector 1500.

For example, the computing device may be provided as a dedicated device for manufacturing the semiconductor device, according to some embodiments, or as a dedicated device for implementing a semiconductor design including the same. For example, the computing device may be equipped with various design and verification simulation programs.

In various embodiments, the processor 1100 may be implemented to control overall operation of the computing device. Furthermore, the processor 1100 may be implemented to execute at least one instruction (or program). The processor 1100 may execute instructions and control the computing device.

In various embodiments, the processor 1100 may execute functions and instructions for execution within the computing device. For example, the processor 1100 may execute instructions stored in the memory 1200 or the storage device 1400. The processor 1100 may perform the operations of FIGS. 1 to 12.

In various embodiments, the processor 1100 may execute software (an application program, an operating system, and a device driver) to be executed on the computing device. The processor 1100 may execute an operating system (OS) loaded into the memory 1200. The processor 1010 may execute various application programs to be driven on the basis of the operating system.

For example, the processor 1100 may be configured to include at least one of a CPU (Central Processing Unit), an MPU (Micro Processor Unit), an MCU (Micro Controller Unit), a GPU (Graphic Processing Unit), an NPU (Neural Processing Unit) or any known type of processor well known in the technical field of the present disclosure. There may be a plurality of processors 1100.

In various embodiments, the memory 1200 may be loaded with an operating system and/or application programs. The OS image stored in the auxiliary storage 1400 may be loaded into the memory 1200 based on a booting sequence when the computing device is booted up. The input/output operations of the computing device may be supported by the operating system. Similarly, the application programs may be loaded into the memory 1200 to select by a user or provide basic services.

For example, the memory 1200 may be a volatile memory, such as a DRAM (dynamic random access memory) and a SRAM (static random access memory), or a non-volatile memory such as a flash memory, a PRAM (phase change random access memory), a RRAM (resistance random access memory), a NFGM (nano floating gate memory), a PoRAM (polymer random access memory), a MRAM (magnetic random access memory) or a FRAM (ferroelectric random access memory).

In various embodiments, the input/output device 1300 may control the user input and output from the user interface devices. For example, the input/output device 1300 may include input means such as a keyboard, a keypad, a mouse, and a touch screen to receive input of information from a designer. A user may receive information about semiconductor regions or data paths which require adjusted operating characteristics, using the input/output device 1300. In addition, the input/output device 1300 may include output means such as a printer and a display to display the detection result of the presence or absence of the MRC violation. For example, the input/output device 1300 may display the attention map of FIG. 11.

In various embodiments, the auxiliary storage 1400 may be provided as a storage medium for a computing device. The auxiliary storage 1400 may store application programs, OS images, and various types of data. The auxiliary storage 1400 may be provided in the form of a mass storage device such as a memory card (MMC, eMMC, SD, MicroSD, etc.), a HDD (hard disk drive), a SSD (solid state drive), and a UFS (universal flash storage).

In various embodiments, the system interconnector 1500 may be a system bus for providing a network within the computing device. The processor 1100, the memory 1200, the input/output device 1300, and the auxiliary storage 1400 are electrically connected and may exchange data with each other through the system interconnector 1500. However, the configuration of the system interconnector 1500 is not limited to the above description and may further include other elements for efficient management.

Although the embodiments of the present inventive concepts have been described above with reference to the accompanying drawings, the present inventive concepts are not limited to the above embodiments, and may be implemented in various forms. Those skilled in the art will appreciate that the present inventive concepts may be embodied in other forms without changing the spirit or features of the present inventive concepts. Accordingly, the above-described embodiments should be understood in all respects as illustrative and not restrictive.

What is claimed is:

1. A method for manufacturing a semiconductor device, the method comprising:
extracting coordinates of vertices of patterns from an optical proximity corrected layout data for an optical proximity corrected layout including the patterns; and
inputting the coordinates of the vertices into a trained transformer model to determine there is a Mask Rule Check (MRC) violation on the optical proximity corrected layout data.

2. The method for manufacturing the semiconductor device of claim 1, wherein
the patterns include a first pattern,
the vertices include a first vertex included in the first pattern, and
extracting the coordinates of the vertices includes extracting a value indicating the first pattern together with the coordinates of the first vertex.

3. The method for manufacturing the semiconductor device of claim 1, wherein
the patterns include a first pattern,
the vertices include a first vertex included in the first pattern, and
extracting the coordinates of the vertex include extracting a value indicating whether the first vertex is the last vertex included in the first pattern, together with the coordinates of the first vertex.

4. The method for manufacturing the semiconductor device of claim 1, wherein
extracting the coordinates of the vertex includes extracting coordinates of each of the vertices.

5. The method for manufacturing the semiconductor device of claim 1,
wherein the patterns are formed in a Bezier curve or a B-spline curve.

6. The method for manufacturing the semiconductor device of claim 5,
wherein the vertices are one or more control points of the curve.

7. The method for manufacturing the semiconductor device of claim 1, further comprising:
generating an attention map according to an attention result of the transformer model.

8. A method for manufacturing a semiconductor device, the method comprising:
acquiring learning data, which includes defective layout data that violates a Mask Rule Check (MRC), and a normal layout data that does not violate the MRC;
tokenizing the learning data;
generating a transformer model using the tokenized learning data;
tokenizing optical proximity corrected layout data; and
inputting the tokenized optical proximity corrected layout data to the transformer model to output whether there is an MRC violation on the optical proximity corrected layout data.

9. The method for manufacturing the semiconductor device of claim 8,
wherein the optical proximity corrected layout data includes data about an optical proximity corrected layout,
the optical proximity corrected layout includes patterns, and
tokenizing the optical proximity corrected layout data includes extracting coordinates of vertices of the patterns.

10. The method for manufacturing the semiconductor device of claim 8,
wherein the optical proximity corrected layout data includes data about the optical proximity corrected layout,
the optical proximity corrected layout includes patterns, and
the patterns are formed in a Bezier curve or a B-spline curve.

11. The method for manufacturing the semiconductor device of claim 8, further comprising:
performing a visual display on a position at which the MRC violation occurs on the optical proximity corrected layout data.

12. The method for manufacturing the semiconductor device of claim 11,
wherein performing the visual indication on the position at which the MRC violation occurs includes generating an attention map of the transformer model.

13. The method for manufacturing the semiconductor device of claim 8,
wherein the transformer model is learned on the basis of a knowledge distillation.

14. The method for manufacturing the semiconductor device of claim 13,
wherein the transformer model is a student model which is learned with a CNN-based model as a teacher model.

15. A computing device comprising:
a memory which stores instructions; and
at least one processor which executes the instructions,
wherein the at least one processor:
generates a learned transformer model, using defective layout data that violates a Mask Rule Check (MRC) and normal layout data that does not violate the MRC,
extracts coordinates of vertices of patterns from optical proximity corrected layout data on an optical proximity corrected layout including the patterns, and
inputs the coordinates of the vertices to the transformer model to output whether there is a MRC violation on the optical proximity corrected layout data.

16. The computing device of claim 15, wherein
the defective layout data that violates the MRC, the normal layout data that does not violate the MRC, and the optical proximity corrected layout data are GDS (Graphic Database System) data.

17. The computing device of claim 15, wherein
the patterns include a first pattern,
the vertices include a first vertex included in the first pattern, and
the at least one processor extracts a value indicating the first pattern, along with the coordinates of the first vertex.

18. The computing device of claim 15, wherein
the patterns include a first pattern,
the vertices include a first vertex included in the first pattern, and
the at least one processor includes extracting a value indicating whether the first vertex is the last vertex included in the first pattern, together with the coordinates of the first vertex.

19. The computing device of claim 15, wherein
the at least one processor generates an attention map on the optical proximity corrected layout data to perform a visual display on a position at which the MRC violation occurs.

20. The computing device of claim 15, wherein
the patterns are formed in a Bezier curve or a B-spline curve, and
the at least one processor extracts coordinates of one or more control points of the curve as the coordinates of the vertices.
